(19) United States
(12) Patent Application Publication
(10) Pub. No.: US 2025/0022491 A1
(43) Pub. Date: Jan. 16, 2025

(54) SYSTEM FOR SAVING LEAKAGE POWER IN STATIC RANDOM ACCESS MEMORY (SRAM) USING LIGHT SLEEP MODE

(71) Applicant: DXCorr Design Inc., Sunnyvale, CA (US)

(72) Inventors: SUDARSHAN KUMAR, BARAUNI (IN); MAYANK TAYAL, BANGALORE (IN); SAGAR VIDYA REDDY, SANTA CLARA, CA (US)

(21) Appl. No.: 18/352,625

(22) Filed: Jul. 14, 2023

(51) Int. Cl. G11C 5/14; G11C 11/417

(52) U.S. Cl. CPC G11C 5/147; G11C 11/417

(57) ABSTRACT

A light sleep power saving system for saving leakage power in a static random access memory (SRAM) is disclosed, the light sleep power saving system is configured to: enable a light sleep (LsEn) mode in a current active cycle: restrict precharging of a plurality of bitlines (BL/BLB) at backend of the current active cycle; analyze that the current active cycle is in the light sleep (LsEn) mode; determine whether the light sleep (LsEn) mode is enabled on at least one cycle ahead to the current active cycle; upon determining, disable the light sleep mode on at least one cycle ahead to the current active cycle; precharge the plurality of bitlines during at least one cycle ahead to the current active cycle; and output the current active cycle comprising access operations on the SRAM. The current active cycle includes access operations that include read and write operations on SRAM.

### FIELD OF INVENTION

Embodiments of the present disclosure relates to a static random access memory (SRAM), and more particularly relates to a system and method for saving leakage power using a light sleep (LS) mode in a static random access memory (SRAM) design.

### BACKGROUND

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Light Sleep (LS) mode is one of the many power saving modes in a static random access memory (SRAM) design with small wake up time and a good amount of leakage power saving. Nearly 8 to 10 percent of standby leakage power can be saved when a memory macro is put in the light sleep mode. But at the same time, it is considered that a good amount of dynamic energy is consumed when the memory macro is put into the light sleep mode and woken up for normal read/write operation.

The consumption of the dynamic energy includes three components. The components include at least one of: a dynamic energy consumed by switching a combinational logic present between a LsEn (Light sleep enable) pin to gating with a bitline precharge generation circuit, switching power of a bitline precharge signal, and power consumed during precharging the bitlines.

There are a number of existing prior art references that disclose light sleep based systems involved in leakage power saving. For example, FIG. 1 is timing diagram 100 for a traditional light sleep usage, in accordance with a prior art reference. The timing diagram 100 of the traditional light sleep usage includes a plurality of digital clock signals with respect to at least one of: a plurality of bitlines (BL) 102, precharge of the plurality of bitlines (BL_PCH) 104, light sleep (LS) signal 106, enabling of read operation (RdEn) 108, and a clock signal (Clk) 110.

Typically, the light sleep mode is suggested to be entered after any active cycle on the SRAM. For example, in FIG. 1, all the three components of the dynamic energy are consumed. Hence, the usage of all the three components of the dynamic energy causes the memory macro to be put in the light sleep mode for a longer time to get any leakage saving benefits. Further, there would be loss of power instead of saving the leakage of power when the memory macro is put for a small amount of time in the light sleep mode and woken up. Further, the above said nodes (e.g., BL, BL_PCH, and the like) switch costing dynamic power without any additional functionality.

Therefore, there is a need for a system and method for saving leakage power using a light sleep (LS) mode in astatic random access memory (SRAM) design to address the aforementioned issues.

### SUMMARY

This summary is provided to introduce a selection of concepts, in a simple manner, which is further described in the detailed description of the disclosure. This summary is neither intended to identify key or essential inventive concepts of the subject matter nor to determine the scope of the disclosure.

In accordance with an embodiment of the present disclosure, a light sleep power saving system for saving leakage power in a static random access memory (SRAM) is disclosed. The light sleep power saving system is configured to: enable a light sleep (LsEn) mode in a current active cycle: restrict precharging of a plurality of bitlines (BL/BLB) at a backend of the current active cycle; to exit light sleep mode, determine whether the light sleep (LsFn) mode is enabled on at least one cycle ahead to the current active cycle; upon determining, disable the light sleep (LsEn) mode on at least one cycle ahead to the current active cycle; precharge the plurality of bitlines (BL/BLB) during at least one cycle ahead to the current active cycle; and output the current active cycle comprising the access operations on the SRAM.

In an embodiment, the current active cycle and the at least one cycle include access operations on the SRAM. In another embodiment, the access operations include at least one of: a read operation, a write operation, and the like on the SRAM. In yet another embodiment, the light sleep power saving system consumes dynamic energy during precharge of the plurality of bitlines (BL/BLB).

In yet another embodiment, the precharging of the plurality of bitlines (BL/BLB) during at least one cycle ahead to the current active cycle requires at least one cycle wake up time. In yet another embodiment, the dynamic energy consumed during precharge of the plurality of bitlines (BL/BLB) corresponds to similar dynamic energy saved during enabling of the light sleep mode in the current active cycle while the precharging of the plurality of bitlines (BL/BLB) is restricted at the backend of the current active cycle.

In one aspect, a light sleep power saving method for saving leakage power in a static random access memory (SRAM) using a light sleep power saving system is disclosed. The light sleep power saving method includes following steps of: (a) enabling a light sleep (LsEn) mode in a current active cycle; (b) restricting precharging of a plurality of bitlines (BL/BLB) at a backend of the current active cycle; (c) determining whether the light sleep (LsEn) mode is enabled on at least one cycle ahead to the current active cycle; (d) upon determining, disabling the light sleep (LsEn) mode on at least one cycle ahead the current active cycle; (e) precharging the plurality of bitlines (BL/BLB) during the at least one cycle ahead to the current active cycle; and (f) outputting the current active cycle comprising the access operations on the SRAM.

To further clarify the advantages and features of the present disclosure, a more particular description of the disclosure will follow by reference to specific embodiments thereof, which are illustrated in the appended figures. It is to be appreciated that these figures depict only typical embodiments of the disclosure and are therefore not to be considered limiting in scope. The disclosure will be described and explained with additional specificity and detail with the appended figures.

### BRIEF DESCRIPTION OF DRAWINGS

The disclosure will be described and explained with additional specificity and detail with the accompanying figures in which:

FIG. 1 is timing diagram for a traditional light sleep usage, in accordance with a prior art reference;

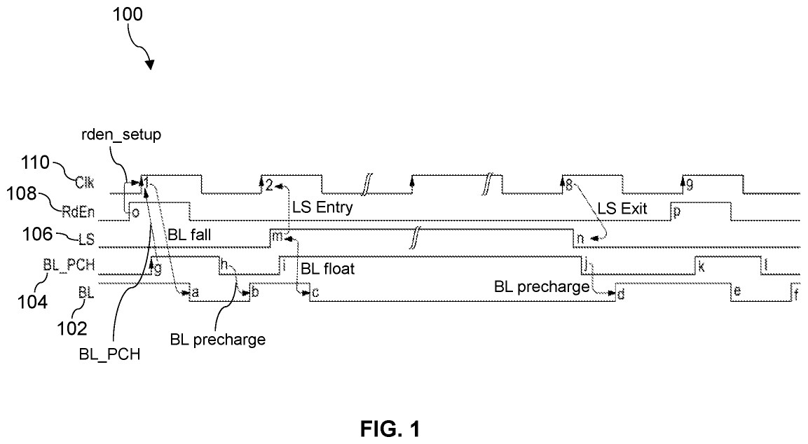

FIG. 2 is a timing diagram for a light sleep power saving system with a light sleep (LS) mode for saving leakage power in a static random access memory (SRAM), in accordance with an embodiment of the present disclosure;

FIG. 3 is a process flow for saving the leakage power in the SRAM using the light sleep power saving system, such as those shown in FIG. 2, in accordance with an embodiment of the present disclosure; and

FIG. 4 illustrates a computer implemented light sleep power saving method for saving leakage power in the light sleep (LS) mode in the static random access memory (SRAM) using a light sleep power saving system, such as those shown in FIG. 3, in accordance with an embodiment of the present disclosure.

Further, those skilled in the art will appreciate that elements in the figures are illustrated for simplicity and may not have necessarily been drawn to scale. Furthermore, in terms of the construction of the device, one or more components of the device may have been represented in the figures by conventional symbols, and the figures may show only those specific details that are pertinent to understanding the embodiments of the present disclosure so as not to obscure the figures with details that will be readily apparent to those skilled in the art having the benefit of the description herein.

### DETAILED DESCRIPTION

For the purpose of promoting an understanding of the principles of the disclosure, reference will now be made to the embodiment illustrated in the figures and specific language will be used to describe them. It will nevertheless be understood that no limitation of the scope of the disclosure is thereby intended. Such alterations and further modifications in the illustrated online platform, and such further applications of the principles of the disclosure as would normally occur to those skilled in the art are to be construed as being within the scope of the present disclosure.

The terms “comprises”, “comprising”, or any other variations thereof, are intended to cover a non-exclusive inclusion, such that a process or method that comprises a list of steps does not include only those steps but may include other steps not expressly listed or inherent to such a process or method. Similarly, one or more devices or subsystems or elements or structures or components preceded by “comprises . . . a” does not, without more constraints, preclude the existence of other devices, subsystems, elements, structures, components, additional devices, additional subsystems, additional elements, additional structures or additional components. Appearances of the phrase “in an embodiment”, “in another embodiment” and similar language throughout this specification may, but not necessarily do, all refer to the same embodiment.

Unless otherwise defined, all technical and scientific terms used herein have the same meaning as commonly understood by those skilled in the art to which this disclosure belongs. The system, methods, and examples provided herein are only illustrative and not intended to be limiting.

In the following specification and the claims, reference will be made to a number of terms, which shall be defined to have the following meanings. “The singular forms” “a”, “an”, and “the” include plural references unless the context clearly dictates otherwise.

A computer system (standalone, client or server computer system) configured by an application may constitute a “module” that is configured and operated to perform certain operations. In one embodiment, the “module” may be implemented mechanically or electronically, so a module may comprise dedicated circuitry or logic that is permanently configured (within a special-purpose processor) to perform certain operations. In another embodiment, a. “module” may also comprise programmable logic or circuitry (as encompassed within a general-purpose processor or other programmable processor) that is temporarily configured by software to perform certain operations.

Accordingly, the term “module” should be understood to encompass a tangible entity, be that an entity that is physically constructed, permanently configured (hardwired) or temporarily configured (programmed) to operate in a certain manner and/or to perform certain operations described herein.

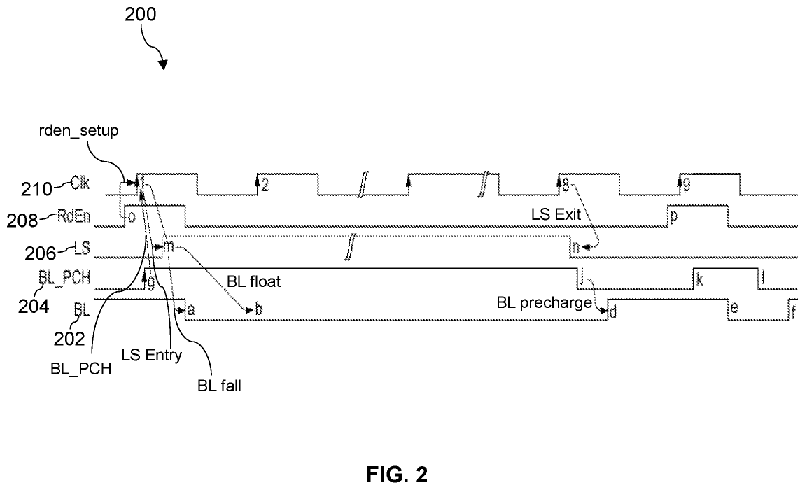

FIG. 2 is a timing diagram 200 for a light sleep power saving system with a light sleep (LS) mode for saving leakage power in a static random access memory (SRAM), in accordance with an embodiment of the present disclosure. The light sleep power saving system with the usage of the light sleep mode saves leakage power in a static random access memory. The light sleep power saving system initially enables the light sleep (LsEn) 206 mode in a current active cycle. In an embodiment, the current active cycle includes access operations on the SRAM. In an embodiment, the access operations include at least one of: a read operation, a write operation, and the like on the SRAM

The light sleep power saving system further restricts precharging 204 of a plurality of bitlines (BL/BLB) 202 at a backend of the current active cycle. The light sleep power saving system further determines whether the light sleep (LsEn) 206 mode is enabled on at least one cycle ahead to the current active cycle. The light sleep power saving system further disables the light sleep (LsEn) 206 mode by switching the LsEn pin to logic zero at least one cycle ahead to the current active cycle. In an embodiment, the at least one cycle includes access operations on the SRAM ahead to the current active cycle. In an embodiment, the access operations of the at least one cycle include at least one of: a read operation, a write operation, and the like on the SRAM.

The light sleep power saving system further precharges 204 the plurality of bitlines (BL_PCH) 202 to the SRAM array supply during the at least one cycle ahead to the current active cycle. In an embodiment, the light sleep power saving system consumes the dynamic energy by bringing the plurality of bitlines 202 from discharged state to voltage level equal to supply voltage for SRAM array during precharge 204 of the plurality of bitlines 202. The light sleep power saving system further outputs (i.e., read or write) the current active cycle including the access operations on the SRAM without loss of dynamic energy.

In an embodiment, the consumption of the dynamic energy may be occurred by at least one of: (a) dynamic energy consumed by a combinational logic present between a LsEn (Light sleep enable) pin to gating with a bitline precharge generation circuit, (b) switching power of a bitline precharge signal 204, and (c) power consumed during precharging the bitlines 202.

The present invention discloses the light sleep power saving system that proposes the usage of the light sleep (LS) mode that the light sleep (LsEn) pin 206 is enabled in the active cycle such that the switching power of the bitline precharge signal, and the power consumed during the precharging 204 of the bitlines 202 are not consumed. This can be further explained as since LsEn pin 206 is made high (i.e., activation of the light sleep signal) during the active cycle, so the precharge process 204 that was supposed to happen at the back end of the active cycle is discontinued and bitlines 202 remain in discharged state. Hence, the light sleep power saving system results in saving the reasonable amount of leakage power.

The timing diagram 200 for the light sleep power saving system with a light sleep (LS) 206 mode includes a plurality of digital clock signals with respect to at least one of: the plurality of bitlines (BL) 202, the precharge of the plurality of bitlines (BL_PCH) 204, the light sleep (LS) signal 206, enabling of read operation (RdEn) 208, and a clock signal (Clk) 210. The read enable signal 208 is made high for a few picoseconds (i.e., minimum time equal to setup time) before an arrival of the clock signal 210. The light sleep (LS) 206 is an asynchronous signal so the light sleep signal 206 can change its state without any dependency on the clock signal 210. The light sleep (LS) 206 going high is considered as LS entry as SRAM enters into the light sleep 206 mode. The light sleep (LS) 206 going low is considered as LS exit as SRAM starts coming out of the light sleep 206 mode. When the SRAM enters into the light sleep 206 mode, the plurality of bitlines (BL) 202 is made to float (i.e., the BL 202 is no longer driven by any device). When the SRAM comes out of the light sleep 206 mode, the plurality of bitlines (BL) 202 is pre-charged to the voltage level equal to the SRAM using a precharging circuit. In an embodiment, the light sleep (LS) signal 206 is an asynchronous signal (i.e., the effect of light sleep (LS) 206 signal on the plurality of bitlines (BL_PCH) 204 signal doesn't wait for clock or any other signal).

FIG. 2 shows that the plurality of bitlines (BL_PCH) 204 signal 204 is moving when the light sleep (LS) signal 206 is also moving as the plurality of bitlines (BL_PCH) 204 signal 204 is dependent on the light sleep (LS) signal 206. Further, when the light sleep (LS) signal 206 is low then the plurality of bitlines (BL_PCH) 204 signal 204 is increased depending on the clock signal (Clk) 210. Further, the timing diagram 200 shows that there is no extra transition occurring on the BL_PCH node 204 and the BL node 202 due to the movement of light sleep (LS) signal 206 in the light sleep power saving system in the SRAM, in FIG. 2.

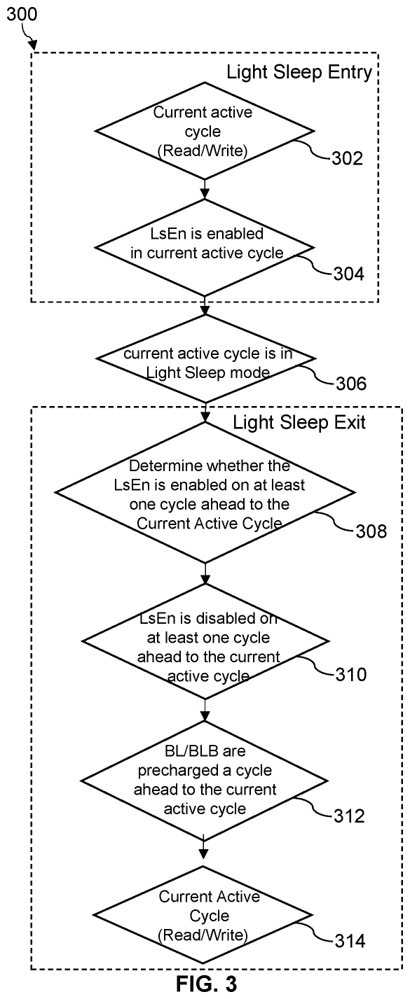

FIG. 3 is a process flow 300 for saving the leakage power in the SRAM using the light sleep power saving system, such as those shown in FIG. 2, in accordance with an embodiment of the present disclosure. At step 302, the SRAM performs access operations in a current active cycle. In an embodiment, the access operations includes at least one of: a read operation, a write operation, and the like on the SEAM. At step 304, the light sleep 206 mode is enabled (LsEn) in the current active cycle using the light sleep power saving system.

In an embodiment, the precharging 204 of the plurality of bitlines 202 is restricted at the backend of the current active cycle. In an embodiment, the restriction of the precharging 204 of the plurality of bitlines (BL/BLB) 202 enables the plurality of bitlines (BL/BLB) 202 to be left for floating (i.e., bitlines 202 are not driven to any of the known logic states (i.e., zero or one)). In other words, the plurality of bitlines (BL/BLB) 202 are inactive while precharging 204 of the plurality of bitlines (BL/BLB) 202 is restricted at the backend of the current active cycle. In another embodiment, the toggling of precharging drivers is not required when the precharging 204 of the plurality of bitlines (BL/BLB) 202 is restricted at the backend of the current active cycle. In other words, when the precharging 204 of the plurality of bitlines (BL/BLB) 202 is restricted at the backend of the current active cycle, the toggling of precharging drivers is inactive.

At step 306, the light sleep power saving system analyzes that the current active cycle is in the light sleep (LsEn) mode 206. At step 308, the light sleep power saving system determines whether the light sleep (LsEn) 206 mode is enabled on at least one cycle ahead to the current active cycle. At step 310, the light sleep 206 (LsEn) mode is disabled at least one cycle ahead to the current active cycle. In an embodiment, the least one cycle includes access operations on the SRAM ahead to the current active cycle. In an embodiment, the access operations include at least one of a read operation, a write operation, and the like on the SRAM. In an embodiment, at least one cycle wake up time is required for precharging 204 of the plurality of bitlines (BL/BLB) 202 during the at least one cycle ahead the current active cycle. For example, the light sleep power saving system utilizes 4 sets of ¼ cycle wake up time that becomes one cycle wake up time for waking up of precharging 204 of the plurality of bitlines (BL/BLB) 202 during the at least one cycle ahead the current active cycle.

At step 312, the plurality of bitlines 202 are precharged 204 during the at least one cycle ahead to the current active cycle. In an embodiment, the light sleep power saving system consumes the dynamic energy during precharge 204 of the plurality of bitlines (BL/BLB) 202. In an embodiment, the dynamic energy consumed during precharge 204 of the plurality of bitlines (BL/BLB) 202 corresponds to similar dynamic energy saved during enabling of the light sleep 206 mode in the current active cycle while the precharging 204 of the plurality of bitlines (BL/BLB) 202 is restricted at the backend of the current active cycle.

At step 314, the current active cycle including the access operations on the SRAM is outputted without loss of the dynamic energy. In an embodiment, the current active cycle is a last active cycle in which the light sleep (LsEn) mode 206 is enabled to restrict consuming of at least one of: the switching power of the bitline precharge signal, and the power during precharging 204 of the plurality of bitlines (BL/LB) 202.

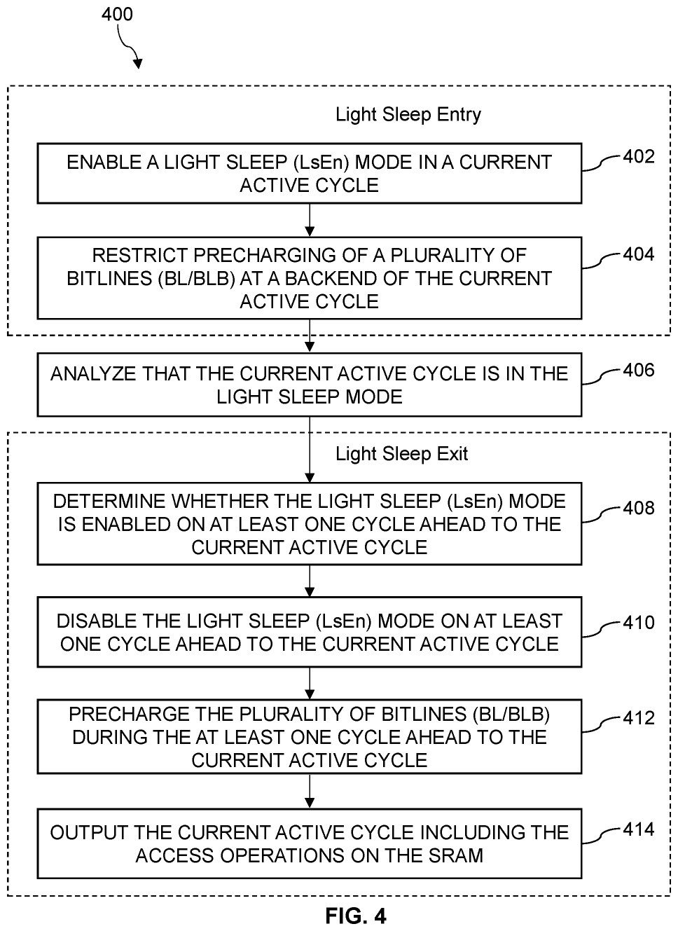

FIG. 4 illustrates a computer implemented light sleep power saving method 400 for saving leak age power in the light sleep (LS) mode in the static random access memory (SRAM) using a light sleep power saving system, such as those shown in FIG. 3, in accordance with an embodiment of the present disclosure. At step 402, the light sleep 206 mode is enabled (LsEn) in the current active cycle. In an embodiment, the current active cycle includes access operations including at least one of: a read operation, a write operation, and the like on the static random access memory.

At step 404, the enabling of the light sleep (LsEn) 206 mode includes a step of restricting precharging 204 of the plurality of bitlines 202 at the backend of the current active cycle. In an embodiment, there is no requirement of precharging drivers for precharging 204 the plurality of bitlines 202 when precharging 204 of the plurality of bitlines 202 is restricted at the backend of the current active cycle. In other words, changing of the precharging drivers may be inactive when precharging 204 of the plurality of bitlines (BL/BLB) 202 is restricted at the backend of the current active cycle. At step 406, the light sleep power saving system analyzes that the current active cycle is in the light sleep (LsEn) 206 mode. At step 408, the light sleep power saving system determines whether the light sleep 206 mode is enabled on at least one cycle ahead to the current active cycle. At step 410, the light sleep 206 mode is disabled on at least one cycle ahead to the current active cycle upon determining 406 that the light sleep 206 mode is enabled on at least one cycle ahead to the current active cycle.

At step 412, the plurality of bitlines 202 are precharged 204 during the at least one cycle ahead to the current active cycle. In an embodiment, at least one cycle wake up time is required for precharging 204 of the plurality of bitlines (BL/BLB) 202 during the at least one cycle ahead to the current active cycle. At step 414, the current active cycle including the access operations on the SRAM is outputted without the loss of the dynamic energy.

The present invention provides the light sleep power saving system that utilizes the light sleep (LS) mode 206 in the current active cycle (i.e., a last active cycle) so that the switching power of the bitline precharge signal, and the power consumed during precharging 204 of the plurality of bitlines (BL/BLB) 202 belonging to the dynamic energy are not consumed. This results in reducing the cost of putting the memory in light sleep 206 mode and thus the memory can be put in light sleep mode more often than the existing approaches. Further, a reasonable amount of saving the leakage power can be achieved using the light sleep power saving system with the usage of the light sleep 206 mode in the SRAM.

The written description describes the subject matter herein to enable any person skilled in the art to make and use the embodiments. The scope of the subject matter embodiments is defined by the claims and may include other modifications that occur to those skilled in the art. Such other modifications are intended to be within the scope of the claims if they have similar elements that do not differ from the literal language of the claims or if they include equivalent elements with insubstantial differences from the literal language of the claims.

The embodiments herein can comprise hardware and software elements. The embodiments that are implemented in software include but are not limited to, firmware, resident software, microcode, etc. The functions performed by various modules described herein may be implemented in other modules or combinations of other modules. For the purposes of this description, a computer-usable or computer-readable medium can be any apparatus that can comprise, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid-state memory, magnetic tape, a removable computer diskette, a random-access memory (RAM), a read-only memory (ROM), a rigid magnetic disk and an optical disk. Current examples of optical disks include compact disk-read only memory (CD-ROM), compact disk-read/write (CD-R/W) and DVD.

Input/output (I/O) devices (including but not limited to keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modem and Ethernet cards are just a few of the currently available types of network adapters.

A representative hardware environment for practicing the embodiments may include a hardware configuration of an information handling/computer system in accordance with the embodiments herein. The system herein comprises at least one processor or central processing unit (CPU). The CPUs are interconnected via system bus to various devices such as a random-access memory (RAM), read-only memory (ROM), and an input/output (1/O) adapter. The I/O adapter can connect to peripheral devices, such as disk units and tape drives, or other program storage devices that are readable by the system. The system can read the inventive instructions on the program storage devices and follow these instructions to execute the methodology of the embodiments herein.

The system further includes a user interface adapter that connects a keyboard, mouse, speaker, microphone, and/or other user interface devices such as a touch screen device (not shown) to the bus to gather user input. Additionally, a communication adapter connects the bus to a data processing network, and a display adapter connects the bus to a display device which may be embodied as an output device such as a monitor, printer, or transmitter, for example.

A description of an embodiment with several components in communication with each other does not imply that all such components are required. On the contrary, a variety of optional components are described to illustrate the wide variety of possible embodiments of the invention. When a single device or article is described herein, it will be apparent that more than one device/article (whether or not they cooperate) may be used in place of a single device/article. Similarly, where more than one device or article is described herein (whether or not they cooperate), it will be apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments of the invention need not include the device itself.

The illustrated steps are set out to explain the exemplary embodiments shown, and it should be anticipated that ongoing technological development will change the manner in which particular functions are performed. These examples are presented herein for purposes of illustration, and not limitation. Further, the boundaries of the functional building blocks have been arbitrarily defined herein for the convenience of the description. Alternative boundaries can be defined so long as the specified functions and relationships thereof are appropriately performed. Alternatives (including equivalents, extensions, variations, deviations, etc., of those described herein) will be apparent to persons skilled in the relevant art(s) based on the teachings contained herein. Such alternatives fall within the scope and spirit of the disclosed embodiments. Also, the words “comprising,” “having,” “containing,” and “including,” and other similar forms are intended to be equivalent in meaning and be open-ended in that an item or items following any one of these words is not meant to be an exhaustive listing of such item or items or meant to be limited to only the listed item or items. It must also be noted that as used herein and in the appended claims, the singular forms “a,” “an,” and “the” include plural references unless the context clearly dictates otherwise.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on. Accordingly, the embodiments of the present invention are intended to be illustrative, but not limiting, of the scope of the invention, which is set forth in the following claims.

What is claimed is:

1. A light sleep power saving system for saving leakage power in a static random access memory (SRAM), the light sleep power saving system is configured to:
enable a light sleep (LsEn) mode in a current active cycle, wherein the current active cycle comprises access operations on the SRAM,
wherein enabling of the light sleep (LsEn) mode comprises:
restricting precharging of a plurality of bitlines (BL/BLB) at a backend of the current active cycle by gating LsEn signal with Precharge enable signal,
analyze that the current active cycle is in the light sleep (LsEn) mode;
determine whether the light sleep (LsEn) mode is enabled on at least one cycle ahead to the current active cycle;
upon determining, disable the light sleep (LsEn) mode on the at least one cycle ahead to the current active cycle, wherein the at least one cycle comprises access operations on the SRAM ahead to the current active cycle;
precharge the plurality of bitlines (BL/BLB) during the at least one cycle ahead to the current active cycle; and
output the current active cycle comprising the access operations on the SRAM.

2. The light sleep power saving system of claim 1, wherein the light sleep power saving system consumes dynamic energy during precharge of the plurality of bitlines (BL/BLB).

3. The light sleep power saving system of claim 2, wherein the consumption of the dynamic energy is occurred by at least one of: (a) dynamic energy consumed by a combinational logic present between a light sleet enable (LsEn) pin to gating with a bitline precharge generation circuit, (b) switching power of a bitline precharge signal, and (c) power consumed during precharging of the plurality of bitlines (BL/BLB).

4. The light sleep power saving system of claim 1, wherein precharging of the plurality of bitlines (BL/BLB) during at least one cycle ahead to the current active cycle requires at least one cycle wake up time.

5. The light sleep power saving system of claim 2, wherein the dynamic energy consumed during precharge of the plurality of bitlines (BL/BLB) corresponds to similar dynamic energy saved during enabling of the light sleep in the current active cycle while the precharging of the plurality of bitlines (BL/BLB) is restricted at the backend of the current active cycle.

6. The light sleep power saving system of claim 1, wherein when the precharging of the plurality of bitlines (BL/BLB) is restricted at the backend of the current active cycle, the toggling of precharging drivers is inactive.

7. The light sleep power saving system of claim 1, wherein the current active cycle is a last active cycle in which the light sleep (LsEn) mode is enabled to restrict consuming of at least one of: the switching power of the bitline precharge signal, and the power during precharging of the plurality of bitlines (BL/BLB).

8. The light sleep power saving system of claim 1, wherein the access operations comprise at least one of a read operation and a write operation on the SRAM.

9. The light sleep power saving system of claim 6, wherein the plurality of bitlines (BL/BLB) are inactive while precharging of the plurality of bitlines (BL/BLB) is restricted at the backend of the current active cycle.

10. A light sleep power saving method for saving leakage power in a static random access memory (SRAM) using a light sleep power saving system, the light sleep power saving method comprising:
enabling a light sleep (LsEn) mode in a current active cycle, wherein the current active cycle comprises access operations on the SRAM,
wherein enabling of the light sleep (LsEn) mode comprises:
restricting precharging of a plurality of bitlines (BL/BLB) at a backend of the current active cycle,
analyzing that the current active cycle is in the light sleep (LsEn) mode;
determining whether the light sleep (LsEn) mode is enabled on at least one cycle ahead to the current active cycle;
upon determining, disabling the light sleep (LsEn) mode on the at least one cycle ahead to the current active cycle, wherein the at least one cycle comprises access operations on the SRAM ahead to the current active cycle;
precharging the plurality of bitlines (BL/BLB) during the at least one cycle ahead to the current active cycle; and
outputting the current active cycle comprising the access operations on the SRAM.

11. The light sleep power saving method of claim 10, further comprising consuming dynamic energy during precharge of the plurality of bitlines (BL/BLB).

12. The light sleep power saving method of claim 11, wherein the consumption of the dynamic energy is occurred by at least one of: (a) dynamic energy consumed by a combinational logic present between a light sleet enable (LsEn) pin to gating with a bitline precharge generation circuit, (b) a switching power of a bitline precharge signal, and (c) power consumed during precharging of the plurality of bitlines (BL/BLB).

13. The light sleep power saving method of claim 10, wherein precharging of the plurality of bitlines (BL/BLB) during at least one cycle ahead to the current active cycle requires at least one cycle wake up time.

14. The light sleep power saving method of claim 10, wherein the dynamic energy consumed during precharge of the plurality of bitlines (BL/BLB) corresponds to similar dynamic energy saved during enabling of the light sleep mode in the current active cycle while the precharging of the plurality of bitlines (BL/BLB) is restricted at the backend of the current active cycle.

15. The light sleep power saving method of claim 10, wherein when the precharging of the plurality of bitlines (BL/BLB) is restricted at the backend of the current active cycle, the toggling of precharging drivers is inactive.

16. The light sleep power saving method of claim 10, wherein the current active cycle is a last active cycle in which the light sleep (LsEn) mode is enabled to restrict consuming of at least one of: the switching power of the bitline precharge signal, and the power during precharging of the plurality of bitlines (BL/BLB).

17. The light sleep power saving method of claim 10, wherein the access operations comprise at least one of: a read operation and a write operation on the SRAM.

18. The light sleep power saving method of claim 15, wherein the plurality of bitlines (BL/BLB) are inactive while precharging of the plurality of bitlines (BL/BLB) is restricted at the backend of the current active cycle.
